(19) United States
(12) Patent Application Publication
(10) Pub. No.: US 2002/0058208 A1
(43) Pub. Date: May 16, 2002

(54) Polymeric substrate circuit protection device and method of making the same

(75) Inventors: Chen-Ron Lin, Hsinchu City (TW); Rei-Yian Chen, Hsin-Shih Village (TW); Ren-Haur Hwang, Taoyuan City (TW); Chih-Yi Chang, Yuanlin Town (CN)

Correspondence Address: Ladas & Parry, 26 West 61st Street, New York, NY, 10023, US

(73) Assignee: PROTECTRONICS TECHNOLOGY CORPORATION

(21) Appl. No.: 09/968,209

(22) Filed: Oct. 1, 2001

(30) Foreign Application Priority Data
Oct. 9, 2000 (TW) 89121127

(51) Int. Cl. G03F 7/00; C25D 5/02

(52) U.S. Cl. 430/311; 430/313; 430/314; 430/318; 205/125

(57) ABSTRACT

The present invention discloses a polymeric circuit protection device and a method of making the same, wherein a highly conductive composite material and a conductive composite material of positive temperature coefficient thermal sensitive resistance are alternately stacked to form a plaque-shaped composite material, then two metal foils are laminated on top surface and bottom surface of the plaque-shaped composite material as electrodes to thereby form a sandwich-like laminated material. Moreover, a cross-linking process is made to cross-link the resin inside the composite material layer. Electrode trenches are etched, and an insulating layer is formed by using green paint in the electrode trenches to isolate different electrodes on the same surface of the device. The highly conductive composite material has more than twenty times the conductivity of the conductive composite material so as to ensure that among connected electrodes inside the plaque-shaped composite material, current mainly flows through the highly conductive composite material rather than the conductive composite material of positive temperature coefficient thermal sensitive resistance.

### BACKGROUND OF THE INVENTION

(A) Field of the Invention

The present invention relates to a polymeric substrate circuit protection device and method of making the same, and in particular, to a polymeric substrate circuit protection device of a surface mounting type and a method of making the same, in which highly conductive composite materials are used as a medium for conducting current between metal electrodes in the device, and thus producing a thermistor device.

(B) Description of Related Art

Thermistor devices are already widely used in various fields, such as temperature detection, security control, temperature compensation, and so on. Over the past years, the thermistor device has mainly been made from ceramic material. However, the ceramic material is formed at high temperature, in most cases, more than 900° C., thus rendering the energy consumption enormous, and the process much complex. Later on, a thermistor device made from a polymeric substrate is developed. As the temperature for manufacturing a thermistor device made from a polymeric substrate is under 300° C., its molding and manufacturing is easier, energy consumption is less, process is easier, and production cost is lower, so that its application has become more and more popular as time goes on.

U.S. Raychem Co. utilizes a polymeric composite material stuffed with a conductive filler to form a series of resettable polymeric positive temperature coefficient (PPTC) devices. The PPTC device is of low resistance at room temperature; however, when a current flowing through the PPTC device is too high, which causes temperature of the PPTC device to reach a certain switching temperature (Ts), resistance of the PPTC device then rises sharply. Thus, it can be applied to designs of an over-current protection device and a temperature-switching device. This is because conductive filler particles in the conductive filler stuffed inside the polymeric composite material of the PPTC device are continuously conductive at room temperature. When the temperature of the PPTC device rises above Ts, volumes of resin in the polymeric composite material expand such that the conductive filler in the polymeric composite material will break down from a continuous status to a discontinuous status. Thus, the resistance of the PPTC device rises sharply so that the current therethrough will be blocked and thereby achieve objects of over-current protection and temperature control switching.

To meet the requirements for applying the PPTC device on printed circuit board surface mounting fabrication, the development of the PPTC device is promoted for a surface-mounting device (SMD). The difference between a SMD-type PPTC device and a conventional socket-type device lies in that all electrodes of the SMD-type PPTC device have to be made on the same side to directly mount a surface of the PPTC device to a printed circuit board.

Raychem Co. utilizes a plate-through-hole method of printed circuit board process to conduct electrodes on top and bottom sides of the PPTC device to the same plane, and then uses a regular process of printed circuit board to form an isolation layer between the electrodes located on the same plane.

Littelfuse Co. proposes another structure and process to manufacture the SMD-type PPTC device. It utilizes electroplating method to form end electrodes conducting to each other on both sides of the PPTC device, and then use the regular process of printed circuit board to manufacture an isolation layer between the electrodes located on the same plane.

The conductance between the top and bottom electrodes of the SMD-type PPTC devices of the two structures described above is made by means of a metal conductive layer formed by the electroplating method. The thermal expansion coefficient of the electroplated metal conductive layer and that of the positive temperature coefficient conductive composite material are quite different. When the PPTC device is heated and thus expands due to an over-current situation, the electroplated metal conductive layer between the top and bottom metal electrodes is apt to break up due to the expansion of the PPTC conductive composite material. Moreover, because the thermal expansion coefficient of the electroplated metal conductive layer between the top and bottom metal electrodes is far smaller than that of the conductive composite material of the PPTC device, when a PPTC device expands due to the heat or over-current situation, the electroplated metal conductive layer will impose restrictions on the thermal expansion of the substrate of the conductive composite material, and thus will affect the disconnection characteristic of a SMD-type PPTC device when a current is overload.

### SUMMARY OF THE INVENTION

An object of the present invention is to provide a polymeric substrate circuit protection device and a method of making the same, in which the substrate of conductive composite material possesses thermal sensitive resistance characteristics to expand freely, thus the continuous conductive filler particles will be disconnected or under a high resistance status under an over-current situation or being heated by an external source, and will further present the best effect to protect circuit.

Another object of the present invention is to provide a polymeric substrate circuit protection device and a method of making the same, in which two conductive materials of different conductive coefficient are utilized between two metal electrodes; and the two conductive materials possess similar expansion coefficients, so that when the PPTC device is heated and thus expands due to an over-current situation, the conducting layer between the top and bottom metal electrodes will not be apt to break up due to the expansion of the conductive composite material of positive temperature coefficient.

Yet another object of the present invention is to provide a polymeric substrate circuit protection device and a method of making the same, which makes the manufacture of the device much easier.

To achieve the objects described above, the present invention provides a polymeric substrate circuit protection device comprising a PTC conductive composite material member and a first highly conductive composite material member. The first highly conductive composite material member and the PTC conductive composite material member together form a substrate, and the first highly conductive composite material member has more than twenty times the conductivity of the PTC conductive composite material member.

A first electrode is provided on a first surface of the substrate. The first electrode comprises a first part and a second part that is discontinuous with the first part, and the first part of the first electrode electrically connects to the first highly conductive composite material member.

Moreover, a second electrode is provided on a second surface of the substrate. The second electrode electrically connects to the first highly conductive composite material member, and an insulating layer is provided at the discontinuous portion between the first part and the second part of the first electrode to isolate one from the other.

Furthermore, the second electrode further comprising a first part and a second part that are discontinuous with the first part, and the second part of the first electrode connects to the second part of the second electrode through a second highly conductive composite material member

The present invention further provides a method of manufacturing a polymeric substrate circuit protection device, the first step is to fabricate a substrate, the substrate comprises a first PTC conductive material member and a second PTC conductive material member, wherein the second conductive material member has more than twenty times the conductivity of the first conductive material member. Then, a first conducting layer used as a first electrode of the device is formed on a first surface of the substrate, and a second conducting layer used as a second electrode of the device is formed as well on a second surface of the substrate to cover the substrate.

Afterward, a first part and a second part of the first electrode are formed; the first part of the first electrode covers the second conductive material member under the first electrode to connect to the second electrode.

Then, parts of the first electrode other than the first part and the second part are removed to thereby form non-conductive discontinuous portions between the first part and the second part, and then forming insulating layers to cap the discontinuous portions between the first part and the second part of the first electrode.

Because the first electrode and the second electrode of the present invention are provided on two surfaces of the conductive composite material, when the device expands due to an over-current situation or being heated up by an external source, the substrate of the conductive composite material of thermal sensitive resistance will expand freely, so that the conductive filler particles inside the resin substrate break down and thus a disconnected status or a high resistance status is obtained, and thereby will present the best effect to protect circuit.

Moreover, the substrate between the first electrode and the second electrode is made from two conductive composite materials with similar thermal expansion coefficient, so that when the PPTC device is heated up and thus expands due to an over-current situation of the circuit protection device. The conducting layer between the top and bottom metal electrodes is not apt to break down because of the expansion of the PTC conductive composite material.

Furthermore, in the method of making a polymeric substrate circuit protection device provided by the present invention, a highly conductive composite material is substituted for a conventional electroplated metal conducting layer. Thus, there is no need to drill and electroplated a conducting layer between the two metal electrodes, making the manufacture of the device much easier.

### BRIEF DESCRIPTION OF THE DRAWINGS

The present invention is described below by way of examples with reference to the accompanying drawings, which will better understand the objects, technical contents, characteristics and effectiveness of the present invention, wherein

FIG. 1 is a plan of a composite material according to a first embodiment of the present invention;

FIG. 2 is a cross-sectional view of the composite material along line A-A′ of FIG. 1;

FIG. 3 is a cross-sectional view of a sandwich-like structure plaque according to the first embodiment of the present invention;

FIG. 4 is a cross-sectional view of a producing process of a circuit protection device according to the first embodiment of the present invention;

FIG. 5 is a cross-sectional view of another producing process of the circuit protection device according to the first embodiment of the present invention;

FIG. 6 is a cross-sectional view of yet another producing process of the circuit protection device according to the first embodiment of the present invention;

FIG. 7 is a cross-sectional view of the circuit protection device according to the first embodiment of the present invention;

FIG. 8 is a cross-sectional view of a producing process of a circuit protection device according to a second embodiment of the present invention;

FIG. 9 is a cross-sectional view of another producing process of the circuit protection device according to the second embodiment of the present invention;

FIG. 10 is a cross-sectional view of the circuit protection device according to the second embodiment of the present invention;

FIG. 11 is a plan of a composite material according to a third embodiment of the present invention;

FIG. 12 is a cross-sectional view of the composite material along line B-B′ of FIG. 11;

FIG. 13 is a cross-sectional view of a sandwich-like structure plaque according to the third embodiment of the present invention;

FIG. 14 is a cross-sectional view of a producing process of a circuit protection device according to the third embodiment of the present invention;

FIG. 15 is a cross-sectional view of another producing process of the circuit protection device according to the third embodiment of the present invention;

FIG. 16 is a cross-sectional view of yet another producing process of the circuit protection device according to the third embodiment of the present invention;

FIG. 17 is a cross-sectional view of the circuit protection device according to the third embodiment of the present invention;

FIG. 18 is a plan of a composite material and trenches according to a fourth embodiment of the present invention;

FIG. 19 is a cross-sectional view of the composite material and trenches along line C-C′ of FIG. 18;

FIG. 20 is a cross-sectional view of the composite material according to the fourth embodiment of the present invention;

FIG. 21 is a cross-sectional view of a sandwich-like structure plaque according to the fourth embodiment of the present invention;

FIG. 22 is a cross-sectional view of a producing process of a circuit protection device according to the fourth embodiment of the present invention;

FIG. 23 is a cross-sectional view of another producing process of the circuit protection device according to the fourth embodiment of the present invention;

FIG. 24 is a cross-sectional view of yet another producing process of the circuit protection device according to the fourth embodiment of the present invention;

FIG. 25 is a cross-sectional view of the circuit protection device according to the fourth embodiment of the present invention;

FIG. 26 is a cross-sectional view of a producing process of a circuit protection device according to a fifth embodiment of the present invention;

FIG. 27 is a cross-sectional view of another producing process of the circuit protection device according to the fifth embodiment of the present invention; and

FIG. 28 is a cross-sectional view of the circuit protection device according to the fifth embodiment of the present invention.

### DETAILED DESCRIPTION OF THE INVENTION

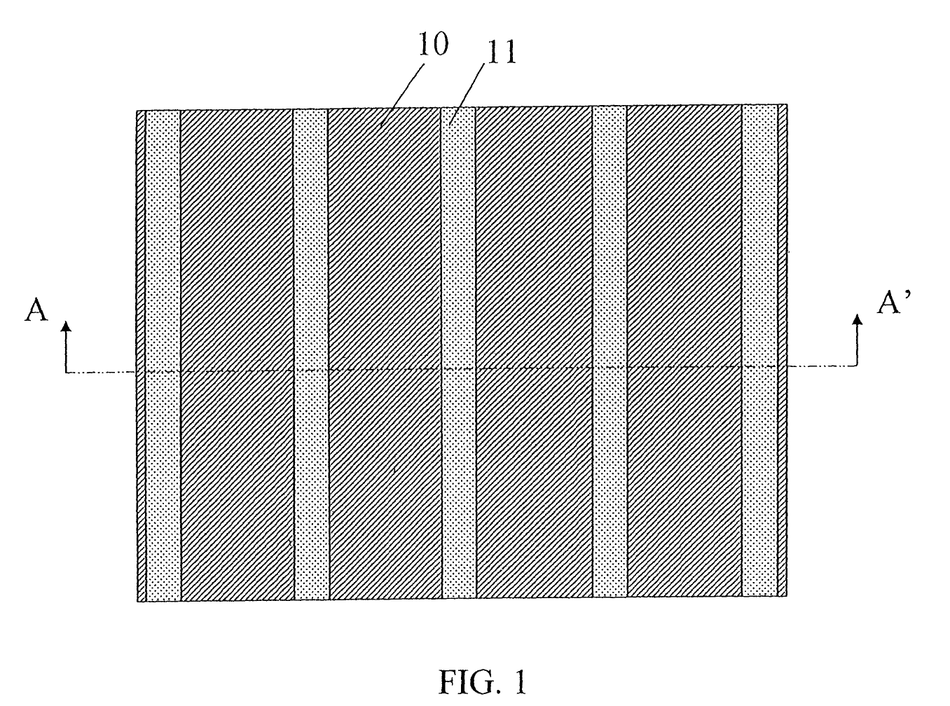

FIGS. 1 to 7 show manufacturing procedures according to a first embodiment of the present invention.

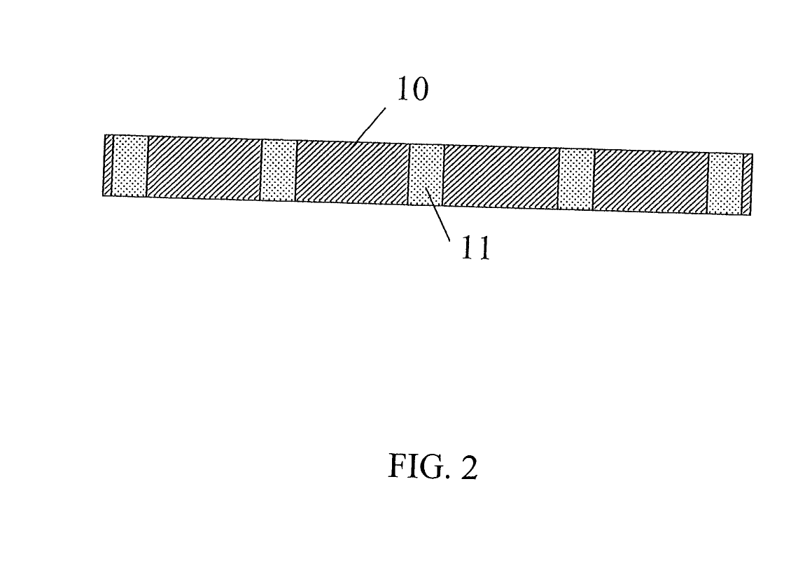

Referring to FIG. 1, a substrate according to a first embodiment of the present invention is composed of a conductive composite material having PTC features 10, a polymeric composite material of positive temperature coefficient thermal sensitive resistance stuffed with conductive fillers, and a first highly conductive composite material 11. The first highly conductive composite material 11 has more than twenty times, preferably fifty times, the conductivity of the conductive composite material having PTC features 10. In the present embodiment, the conductive composite material having PTC features 10 may be a plaque-shaped material made from the mixture of polyethylene Petrothene LB832 (which is commercially available from Equistar Co. of U.S.) and carbon black Raven 450 (which is commercially available from Columbian Co. of U.S.) at the weight ratio of 1 to 1. The first highly conductive composite material 11 may be another plaque-shaped material made from the mixture of PE LH606 (which is commercially available from USI Far East Co. of Taiwan) and a conducting metal nickel powder at the weight ratio of 3 to 17. Then, the conductive composite material having PTC features 10 and the first highly conductive composite material 11 are stacked alternately to form a plaque-shaped material as shown in FIG. 1. If the plaque-shaped material is cut off along line A to A′, its cross-sectional view is shown in FIG. 2.

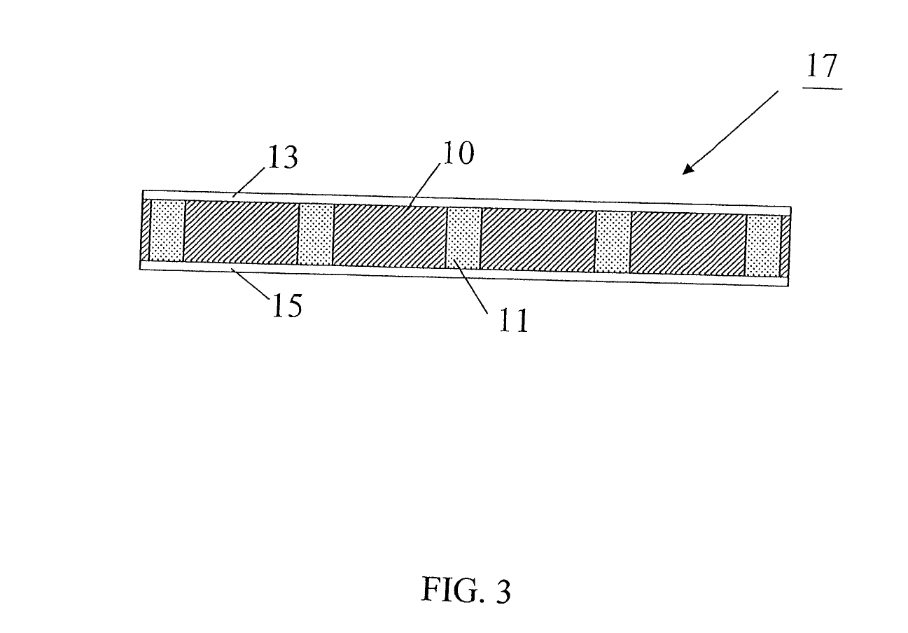

Referring to FIG. 3, copper foils 13 and 15 disposed on top and bottom surfaces of the composite material plaque, respectively, are used for electrodes of a PTC device. Other suitable foils, such as nickel foil, can be used as well. After being hot pressed, a plaque 17 of sandwich-like structure is obtained, wherein the top and bottom layers are copper foils, and the intermediate layer is an alternate structure of the conductive composite material having PTC features 10 and the highly conductive composite material 11. The plaque 17 is then irradiated by Co-60 with a dosage of 20 Mrads such that the conductive composite material having PTC features 10 and the highly conductive composite material 11 couple with each other and thus have a shape-memory property.

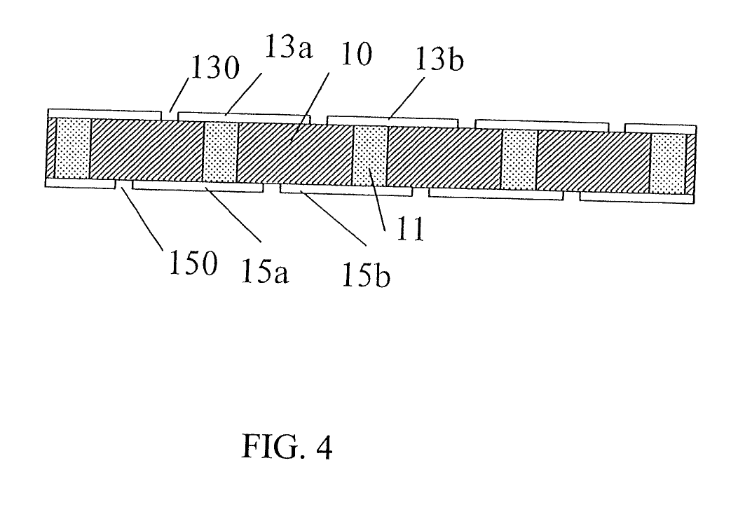

Referring to FIG. 4, the top and bottom electrode layers 13 and 15 of copper foil are exposed, developed and etched according to a conventional lithographic process to form top electrodes 13a and 13b, a top isolation trench 130, bottom electrodes 15a and 15b, and a bottom isolation trench 150 of the shape as illustrated.

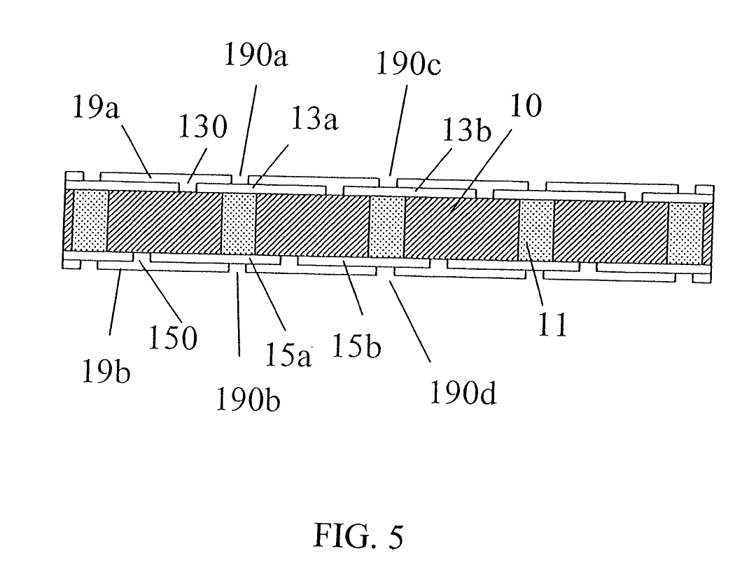

Referring to FIG. 5, the etched plaque 17 is printed with a solder mask (a thick film ceramic insulating material can be used as well, for the purpose of electrically insulating) through a conventional process of manufacturing a printed circuit board so as to form insulating layers 19a and 19b between the top metal electrodes 13a and 13b, and the bottom metal electrodes 15a and 15b, respectively. The solder mask covers the top isolation trench 130 as well as the bottom isolation trench 150, with insulating layer trenches 190a, 190b, 190c, and 190d uncovered for conducting areas.

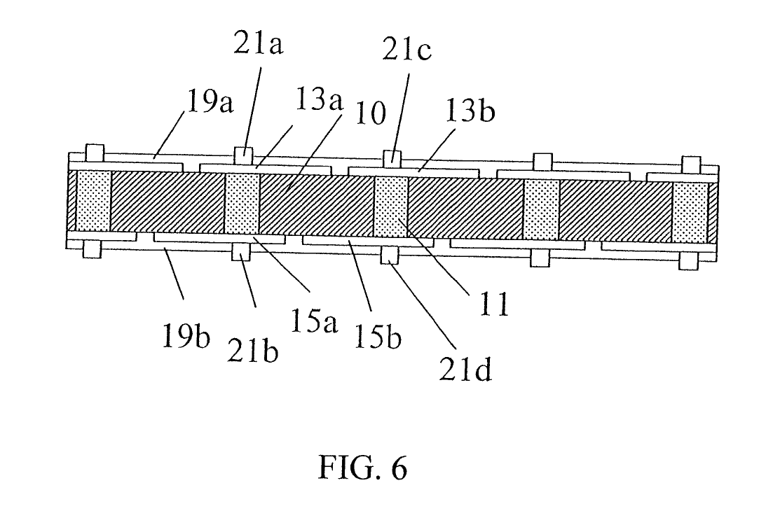

Referring to FIG. 6, an electroless plating process, an electroplating process, and a tin soldering process are sequentially proceeded to form metal soldering points 21a, 21b, 21c, and 21d, which are used for conducting points, in the insulating layer trenches 190a, 190b, 190c, and 190d.

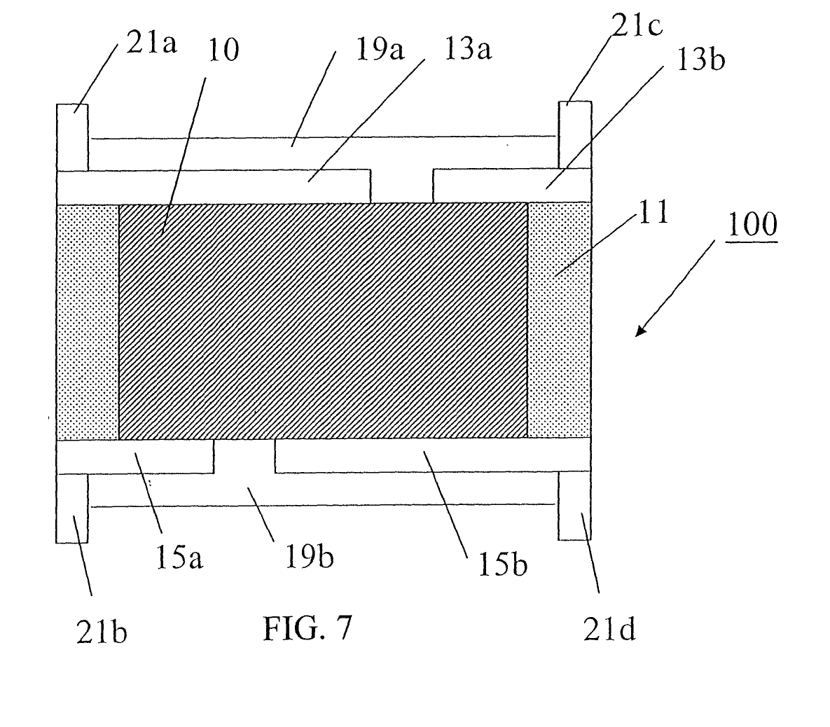

Referring to FIG. 7, the plaque 17 is diced off with a suitable tool, such as a diamond knife along the metal soldering points 21a, 21b, 21c, and 21d to form a PPTC device 100. In operation, the metal soldering points 21a and 21c as well as the metal soldering points 21b and 21d can be used as contacts, and thus a two-sided polymeric substrate circuit protection device is obtained.

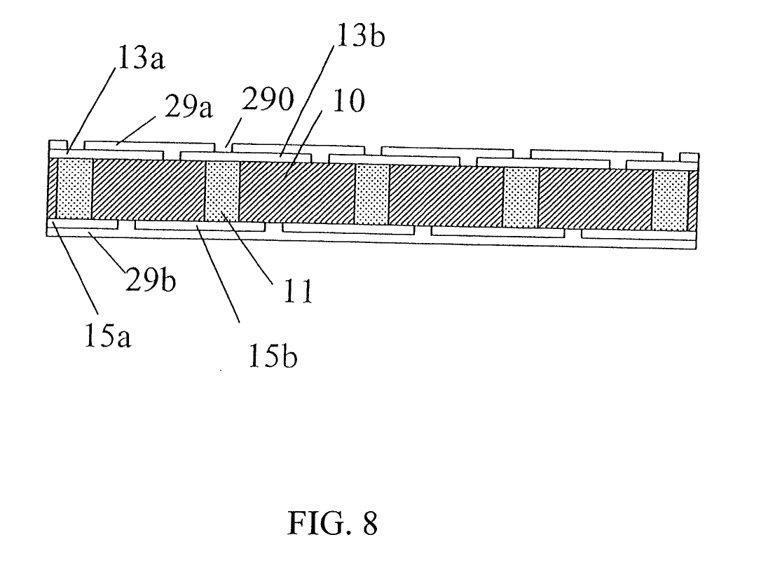

FIGS. 8 to 10 depict manufacturing procedures according to a second embodiment of the present invention. They are directed to a modified embodiment following the process of FIG. 1 to FIG. 4.

In FIG. 4, the top electrodes 13a and 13b, a top isolation trench 130, bottom electrodes 15a and 15b, and a bottom isolation trench 150 have already been formed on the top and bottom electrodes of the plaque 17.

Then, referring to FIG. 8, the etched plaque 17 is printed with a solder mask through a conventional process of manufacturing a printed circuit board to form insulating layers 29a and 29b between the top metal electrodes 13a and 13b, and the bottom metal electrodes 15a and 15b, respectively. The solder mask covers the top isolation trench 130 as well as the bottom isolation trench 150, with a top insulating layer trench 290 uncovered for conducting areas.

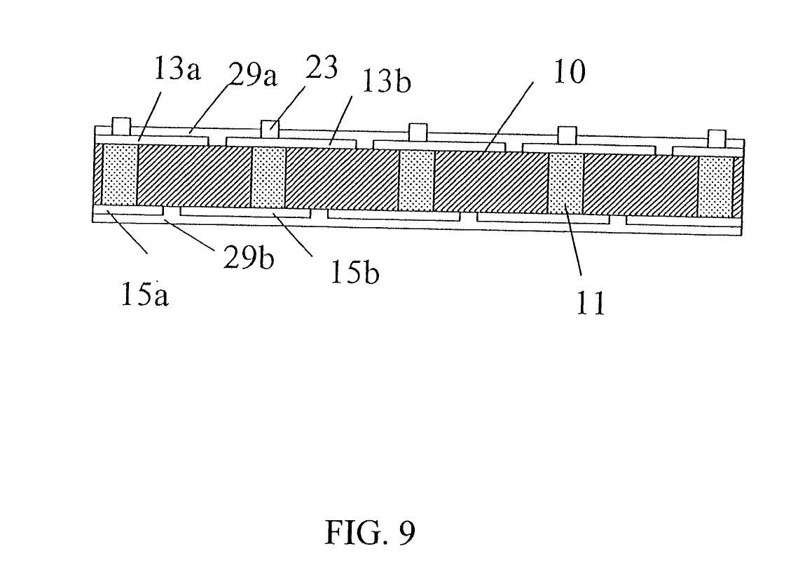

Referring to FIG. 9, an electroless plating process, an electroplating process, and a tin soldering process are sequentially proceeded to form metal soldering points 23, which are used for conducting points, in the top insulating layer trench 290.

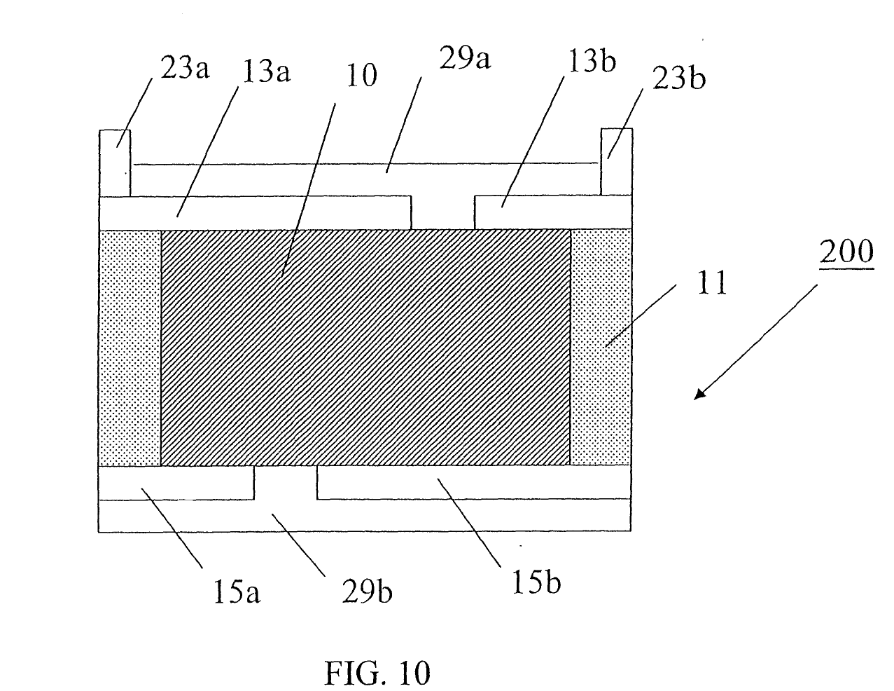

Referring to FIG. 10, the plaque 17 is diced off with a suitable tool, such as a diamond knife, along the metal soldering points 23 to form an individual PPTC device 200. Because the metal soldering points 23a and 23b used for end electrodes in this embodiment are on the same surface, the device 200 is a single-sided type surface mountable polymeric substrate circuit protection device.

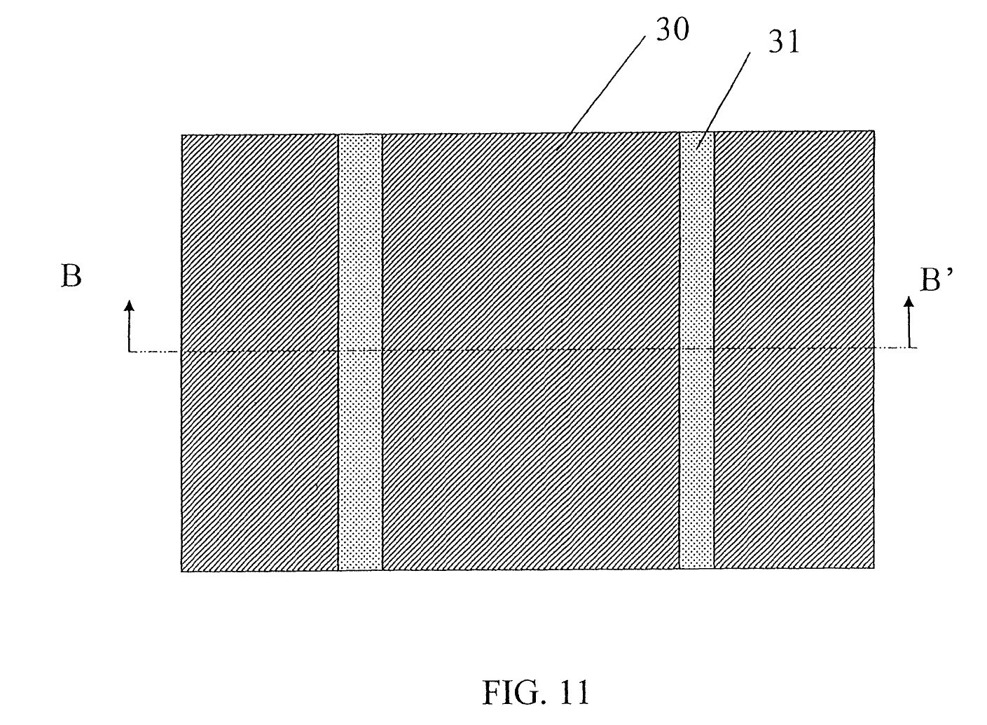

FIGS. 11 to 17 depicts manufacturing procedures according to a third embodiment of the present invention.

Referring to FIG. 11, in this embodiment, a plaque-shaped conductive composite material having PTC features 30 of PTC type is made from the mixture of polyethylene Petrothene LB832 (which is commercially available from Equistar Co. of U.S.) and carbon black Raven 450 (which is commercially available from Columbian Co. of U.S.) at the weight ratio of 1 to 1. A plaque-shaped highly conductive composite material 31 is made from the mixture of PE LH606 (which is commercially available from USI Far East Co. of Taiwan) and a conducting metal nickel powder at the weight ratio of 3 to 17.

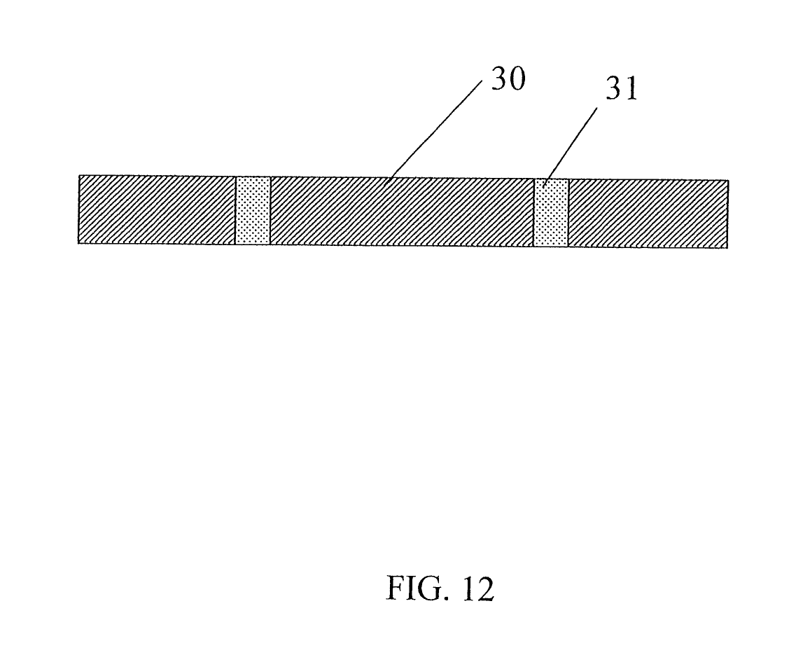

The conductive composite material having PTC features 30 and the highly conductive composite material 31 are alternately interlaced in a molding apparatus to form a substrate as shown in FIG. 11. If the integrated substrate is diced off along line BB′, a cross-sectional view of the composite material plaque is obtained as shown in FIG. 12.

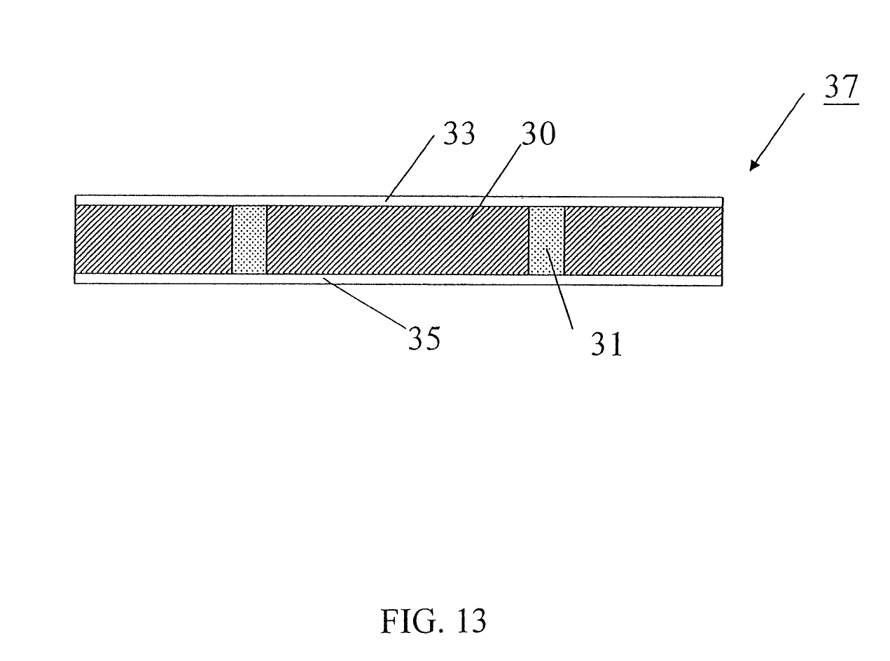

Referring to FIG. 13, copper foils 33 and 35 are disposed on top and bottom surfaces of a composite material plaque, respectively as electrodes. After being hot pressed, a sandwich-like plaque 37 is obtained, wherein copper foils 33 and 35 form its top and bottom layers, and the conductive composite material having PTC features 30 and the highly conductive composite material 31 form its intermediate layer. The sandwich-like plaque 37 is then irradiated by Co-60 with a dosage of 20 Mrads, so that the conductive composite material having PTC features 30 and the highly conductive composite material 31 couple with each other and thus has a shape-memory property.

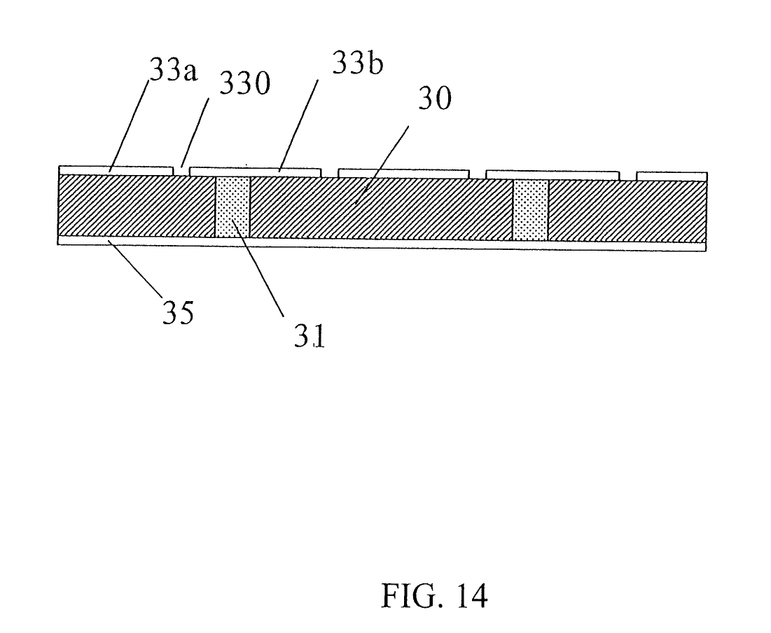

Referring to FIG. 14, the top electrode layer 33 of copper foil are exposed, developed, and etched according to a conventional lithographic process to form top electrodes 33a and 33b, and a top isolation trench 330 as illustrated.

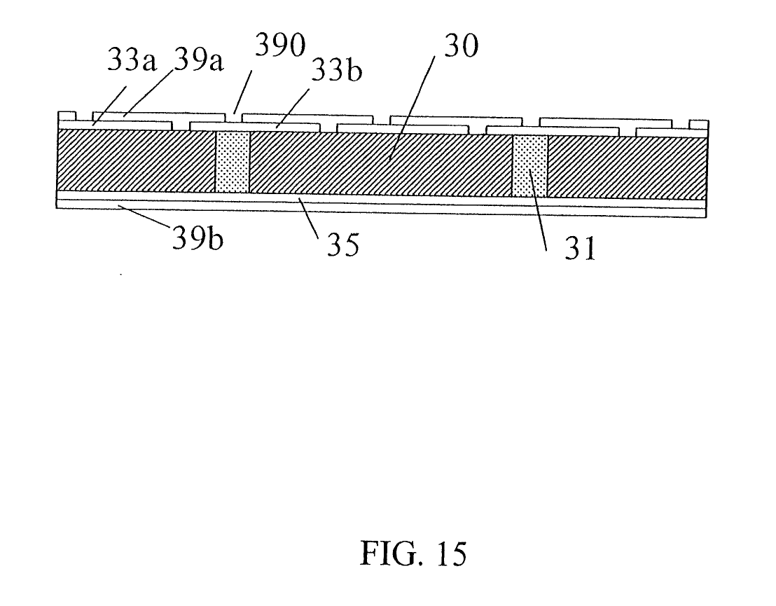

Referring to FIG. 15, the etched sandwich-like structure plaque 37 is printed with a solder mask over its top and bottom surfaces through a conventional process of manufacturing a printed circuit board to form an insulating layer 39a between top metal electrodes 33a and 33b, a top insulating layer trench 390, which is used for a conducting area, and an insulating layer 39b for the bottom metal electrode 35.

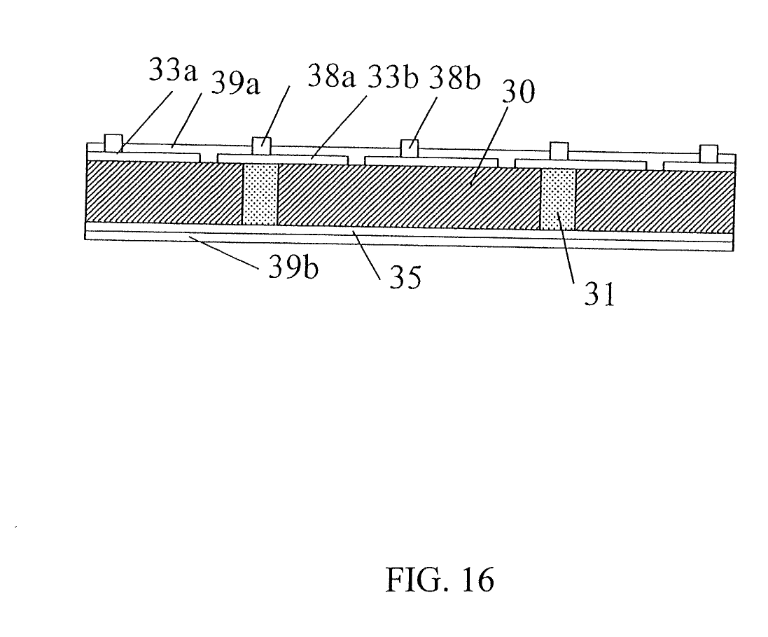

Referring to FIG. 16, an electroless plating process, an electroplating process, and a soldering process are further proceeded to form metal soldering points 38a and 38b in the top insulating layer trench 390 and top insulating layer for soldering of the top metal electrode.

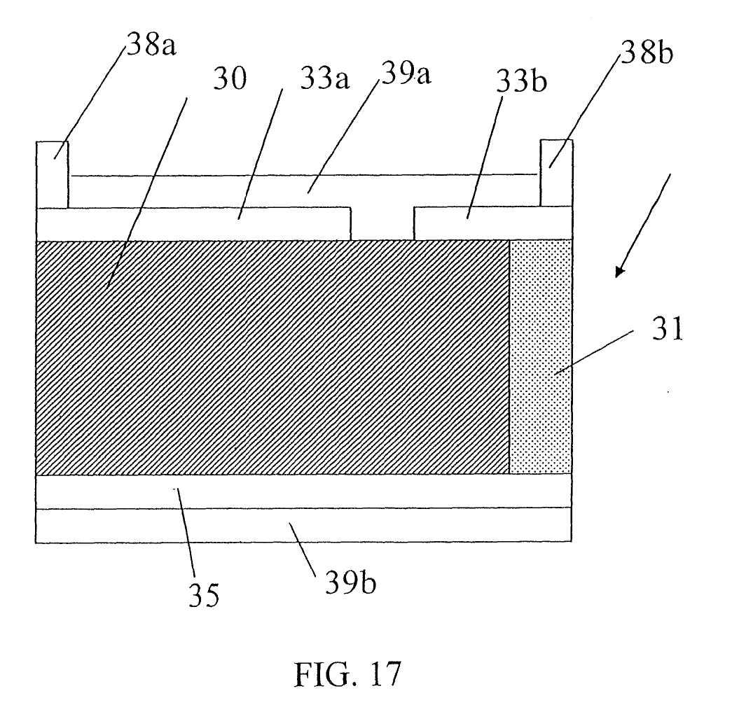

Referring to FIG. 17, the device is diced off with a diamond knife along the metal soldering points to form an individual surface mountable circuit protection device 300.

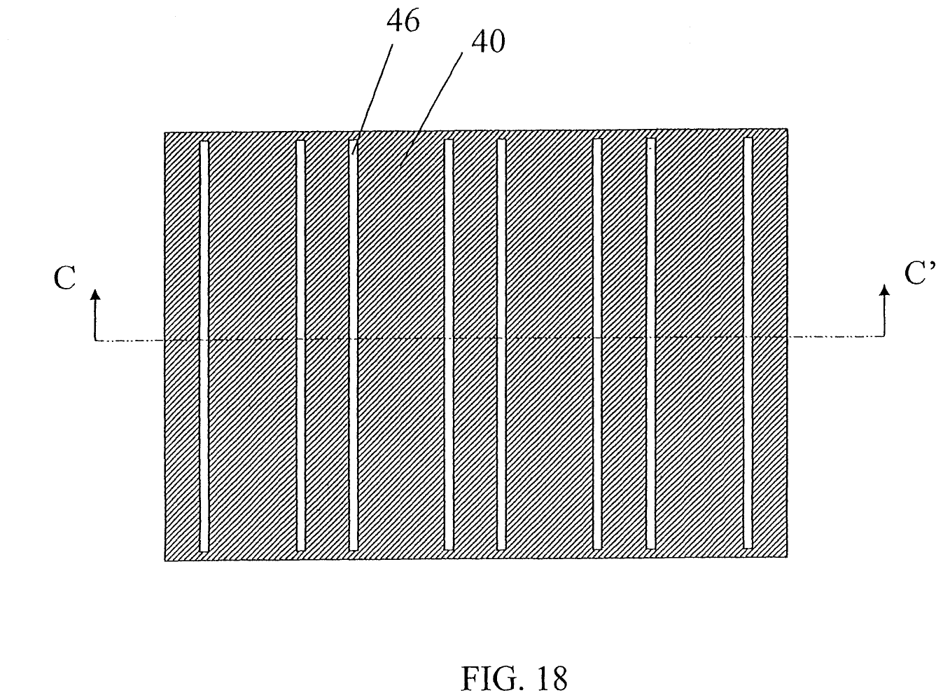

FIGS. 18 to 25 depicts manufacturing procedures according to a fourth embodiment of the present invention.

In FIG. 18, a PTC polymeric composite material having PTC features 40 is a plaque-shaped material made from the mixture of polyethylene Petrothene LB832 (which is commercially available from Equistar Co. of U.S.) and carbon black Raven 450 (which is commercially available from Columbian Co. of U.S.) at the weight ratio of 1 to 1. The plaque-shaped material is further stamped to form strip-shaped trenches 46 of appropriate width.

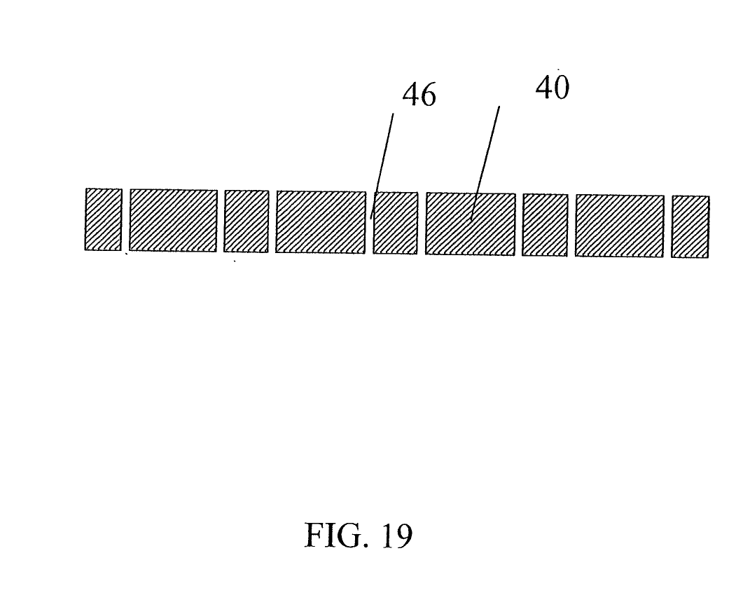

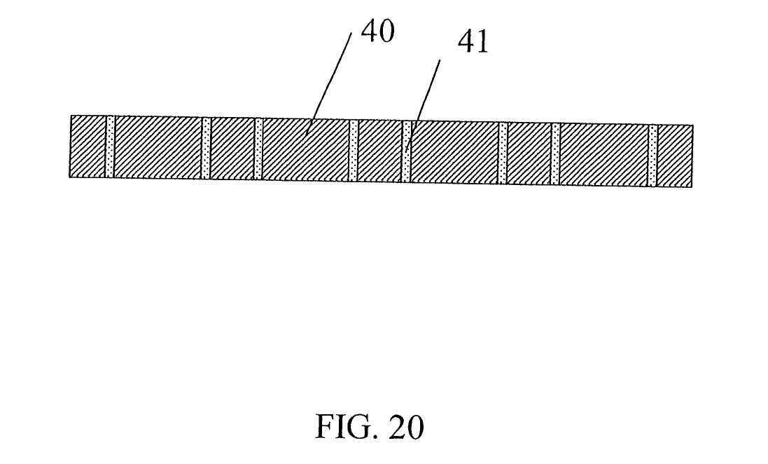

FIG. 19 is a cross-sectional view of the plaque-shaped material of FIG. 18 taken along line C-C′. A highly conductive composite material 41 is made from the mixture of PE LH606 (which is commercially available from USI Far East Co of Taiwan) and a conducting metal nickel powder at the weight ratio of 3 to 17. The highly conductive composite material 41 is then embedded into the strip-shaped trenches 46, and then the structure of a cross-sectional view as shown in FIG. 20 is obtained.

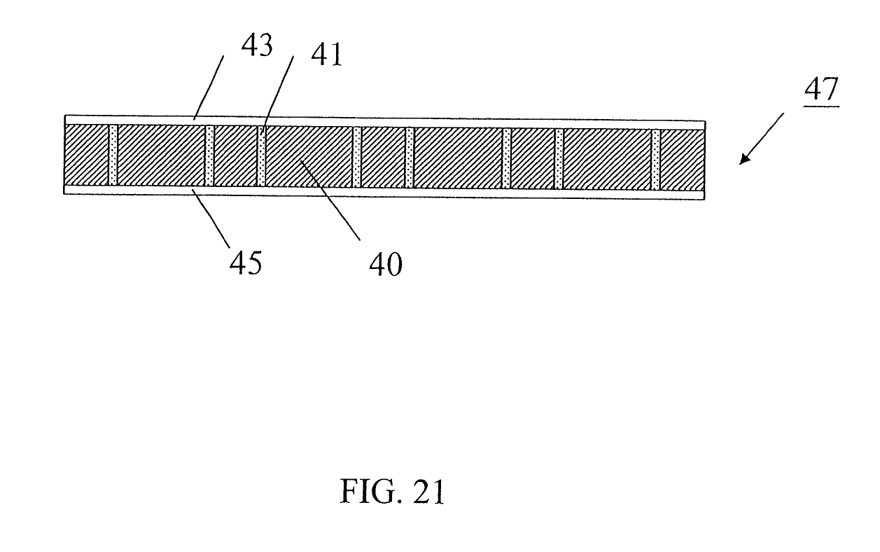

Referring to FIG. 21, copper foils 43 and 45 are disposed on top and bottom surfaces of the composite material plaque, respectively. After being hot pressed, a sandwich-like structure plaque 47 is obtained, wherein copper foils form its top and bottom layers, and the conductive composite material having PTC features 40 and the highly conductive composite material 41 together form its intermediate layer. The sandwich-like structure plaque 47 is then irradiated by Co-60 with a dosage of 20 Mrads, so that the conductive composite material having PTC features 40 and the highly conductive composite material 41 couple with each other and thus have a shape-memory property.

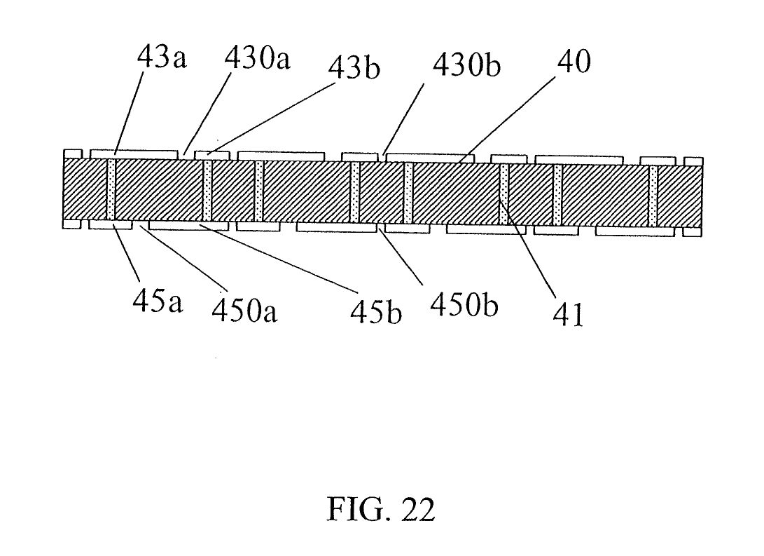

Referring to FIG. 22, the top and bottom electrode layers 43 and 45 of copper foil are conducted by an etching process to form top electrodes 43a and 43b, top isolation trenches 430a and 430b, bottom electrodes 45a and 45b, and bottom isolation trenches 450a and 450b of the shape as illustrated.

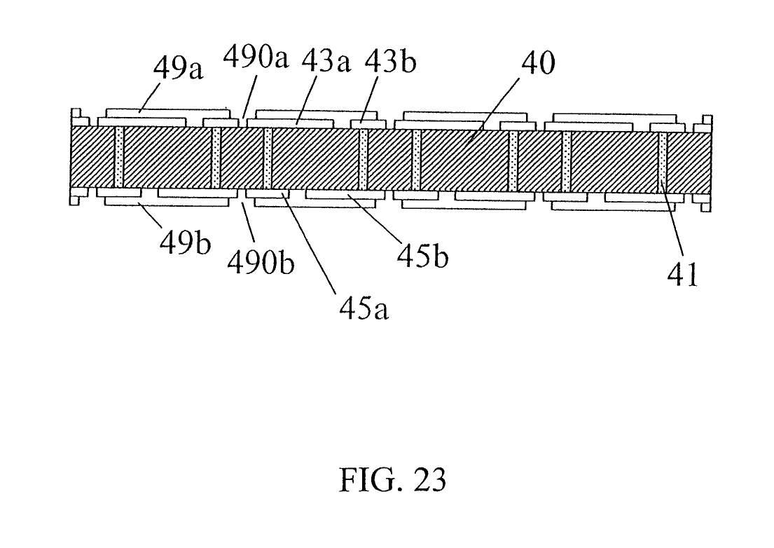

Referring to FIG. 23, the etched sandwich-like structure plaque 47 is printed with a solder mask according to a conventional process of manufacturing a printed circuit board to form an insulating layer 49a between top metal electrodes, a top insulating layer trench 490a, an insulating layer 49b between bottom metal electrodes, and a bottom insulating layer trench 490b.

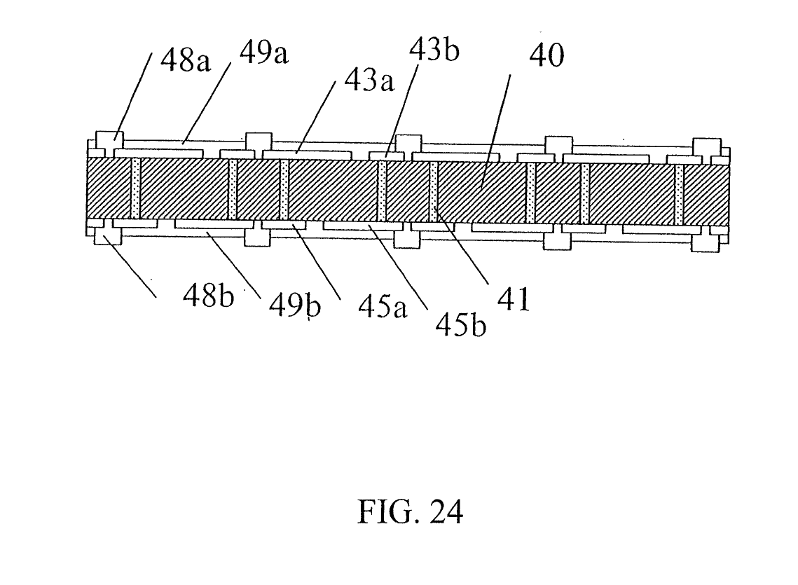

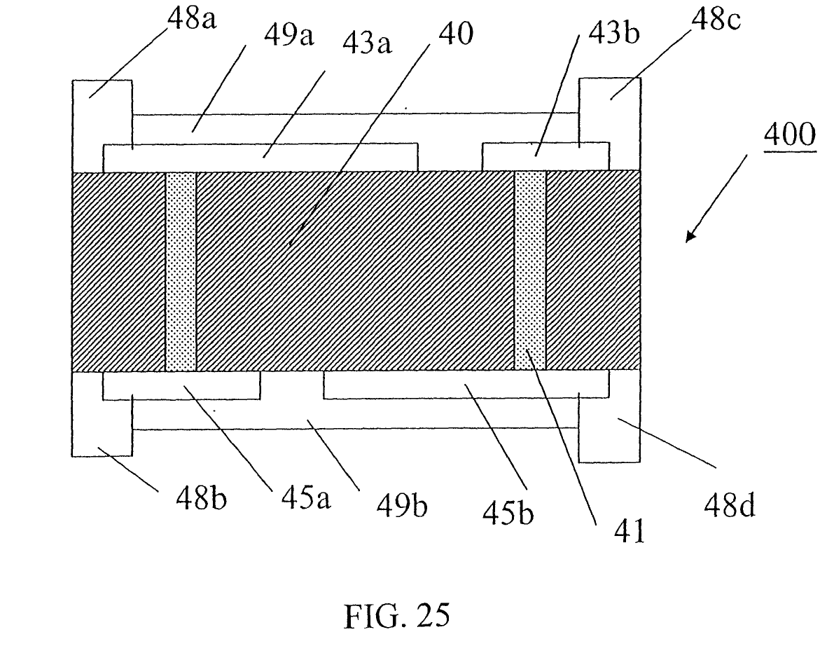

Referring to FIG. 24, an electroless plating process, an electroplating process, and a soldering process are sequentially made to form metal soldering points 48a and 48c of the top metal electrodes and metal soldering points 48b and 48d of the bottom metal electrodes for soldering. Then an individual surface mountable circuit protection device 400 is formed by dicing with a diamond knife along the metal soldering points 48a, 48b, 48c, and 48d as shown in FIG. 25. In this embodiment, the metal soldering point 48a, the highly conductive composite material 41, and the metal soldering point 48b are not disposed in a line.

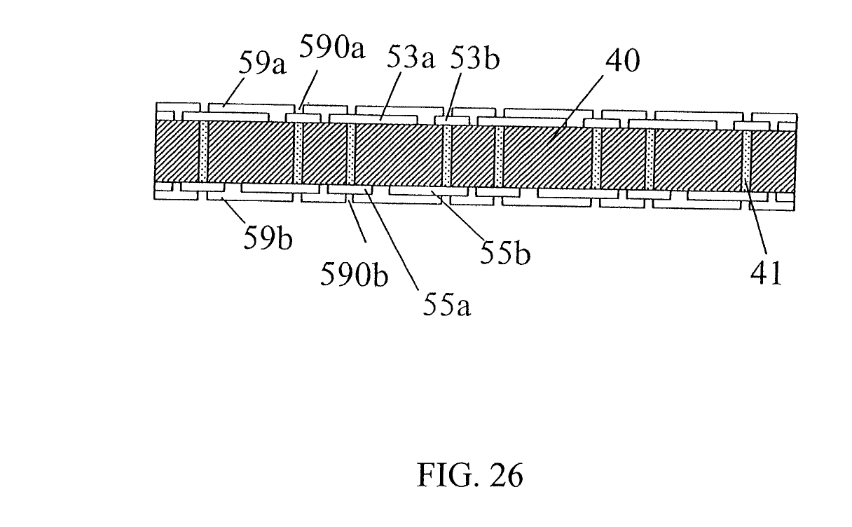

FIGS. 26 to 28 depict manufacturing procedures according to a fifth embodiment of the present invention. The process of FIG. 26 follows the process of FIG. 18 to FIG. 22. Referring to FIG. 26, the etched sandwich-like structure plaque 47 is printed with a solder mask according to a conventional process of manufacturing a printed circuit board to form an insulating layer 59a between top metal electrodes, a top insulating layer trench 590a, an insulating layer 59b between bottom metal electrodes, and a bottom insulating layer trench 590b.

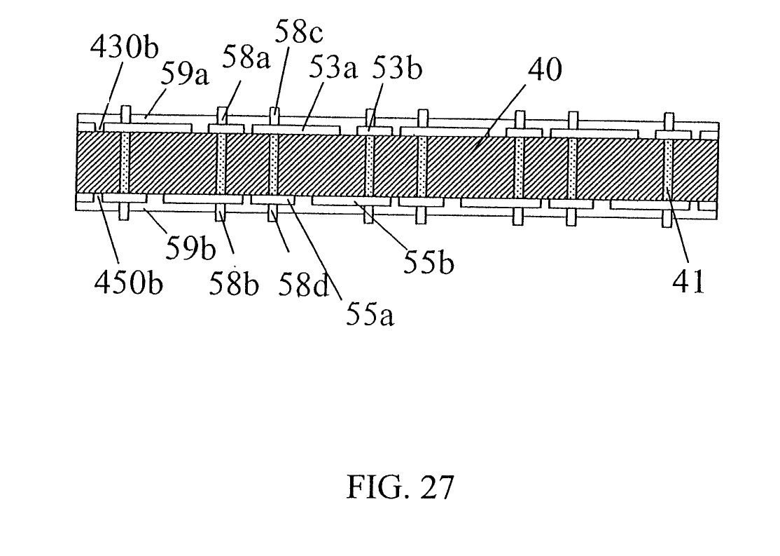

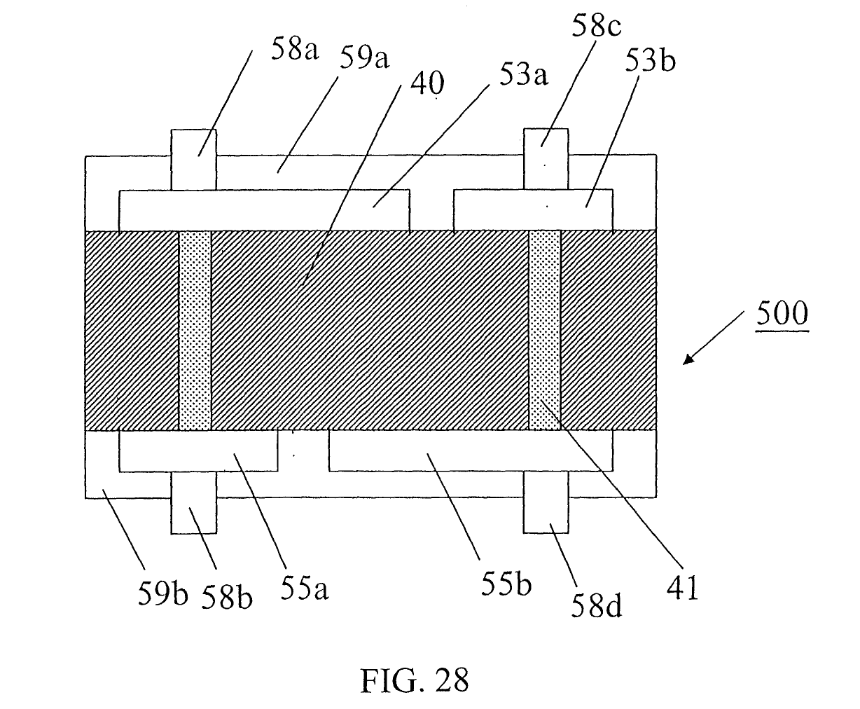

Referring to FIG. 27, an electroless plating process, an electroplating process, and a soldering process are sequentially made to form metal soldering points 58a and 58c of the top metal electrodes and metal soldering points 58b and 58d of the bottom metal electrodes for soldering. Referring to FIG. 28, a surface mountable circuit protection device 500 is formed by dicing with a diamond knife along positions 430b and 450b. In this embodiment, the metal soldering point 58c, the highly conductive composite material 41, and the metal soldering point 58d are disposed in a line.

The materials of the key elements of the present invention can be changed to obtain the device of different characteristics. For example, in the first embodiment, the conductive composite material having PTC features 10 can also be a plaque-shaped material made from the mixture of polyethylene LH606 (which is commercially available from USI Far East Co. of Taiwan ) and carbon black Raven 420 (which is commercially available from Columbian Co. of U.S.) at the weight ratio of 11 to 9. The highly conductive composite material 11 is a half solid (B-stage) plaque made from the mixture of epoxy resin and silver powder at the weight ratio of 13 to 87, wherein the formula of the epoxy resin is 100 parts by weight of epoxy resin Epon 1001 (which is commercially available from Shell Chemical Co.), 4 parts by weight of Dicyanodiamide (which is commercially available from Merck Co.), and 0.2 parts by weight of Benzyldimethylamine (which is commercially available from Merck Co.).

Moreover, in the present invention, a plaque-shaped material made from the mixture of 55 weight percentage of polyethylene LH 606 (which is commercially available from USI Far East Co. of Taiwan) and 45 weight percentage of carbon black Raven 420 (which is commercially available from Columbian Co. of U.S.) can be used as the conductive composite material having PTC features 10 (referring to the first embodiment). And a half solid (B-stage) plaque-shaped material made from the mixture of 45 weight percentage of epoxy resin, 45 weight percentage of silver plated hollow glass ball Conduct-O-Fil SH400S33 (which is commercially available from Potters Co. of U.S.), and 10 weight percentage of carbon black XC-72 (which is commercially available from Cabot Co. of U.S.) can be used as the highly conductive composite material 11. Thus a device of different characteristics is obtained, wherein, the formula of the epoxy resin is the mixture of 100 parts by weight of epoxy resin Epon 1001 (which is commercially available from Shell Chemical Co.), 4 parts by weight of Dicyanodiamide (which is commercially available from Merck Co.), and 0.2 part by weight of Benzyldimethylamine (which is commercially available from Merck Co.).

The technical contents and features of the present invention have been disclosed in the above embodiments and will not be limited thereto. Persons skilled in the art can possibly modify or change the details in accordance with the present invention, such as by changing the selected polymer material, or adding different conductive particles or varying the weight ratio of the constitutions to achieve the same effectiveness, without departing from the technologic ideas and spirits of the invention.

What is claimed is:

1. A method for manufacturing a polymeric substrate circuit protection device, comprising the steps of:
providing a conductive composite material having PTC features and a highly conductive composite material, the highly conductive composite material having more than twenty times the conductivity of the conductive composite material;
alternately interlacing the conductive composite material and the highly conductive composite material to form a substrate;
forming a first conducting layer and a second conducting layer on a first surface and a second surface of the substrate, respectively, wherein the highly conductive composite material is interposed between the first conducting layer and the second conducting layer for conducting the first conducting layer to the second conducting layer;
pressing and crosslinking the first conducting layer, the second conducting layer, the conductive composite material, and the highly conductive composite material;
exposing, developing , and etching the first conducting layer and the second conducting layer to form a first discontinuous portion and a second discontinuous portion of the first conducting layer and the second conducting layer, respectively, wherein the first conducting layer has a first part and a second part, and the second conducting layer has a first part and a second part, the first part of the first conducting layer being connected to the first part of the second conducting layer through the highly conductive composite material;
forming an insulating layer on the first conducting layer, the second conducting layer, the first discontinuous portion and the second discontinuous portion, with contact portions left on the first part of the first conducting layer and the second part of the first conducting layer; and
forming contacts at the contact portions of the first part of the first conducting layer and the second part of the first conducting layer.

2. The method according to claim 1, wherein the conductive composite material is consisted of polyethylene and carbon black.

3. The method according to claim 1, wherein the conductive composite material is made by mixing polyethylene and carbon black at the weight ratio of 1 to 1.

4. The method according to claim 1, wherein the first surface and the second surface are a top surface and a bottom surface of the substrate, respectively.

5. The method according to claim 1, wherein the first discontinuous portion is a trench.

6. The method according to claim 1, wherein the insulating layer is a soldering mask.

7. A polymeric substrate circuit protection device comprising:
a conductive composite material member having PTC features;
a first highly conductive composite material member, and the conductive composite material member having PTC features form a substrate; the first highly conductive composite material member having more than twenty times the conductivity of the conductive composite material member having PTC features;
a first electrode provided on a first surface of the substrate, comprising a first part and a second part, which are discontinuous, wherein the first part of the first electrode is electrically connected to the first highly conductive composite material member;
a second electrode provided on a second surface of the substrate, having electrically connected to the first highly conductive composite material member; and
an insulating layer located at the discontinuous portion of the first part and the second part of the first electrode.

8. The device according to claim 7, further comprising a second highly conductive composite material member, and the second electrode comprising a first part and a second part, which are discontinuous, wherein the second part of the first electrode is electrically connected to the second part of the second electrode via the second highly conductive composite material member.

9. The device according to claim 7, wherein the second electrode comprises the first part and the second part, which are discontinuous, the first part of the first electrode is electrically connected to the first part of the second electrode through the first highly conductive composite material member under the first part of the first electrode, and both the first part of the first electrode and the second part of the first electrode are provided with contacts, the contacts of the first part of the first electrode are disposed in a line with the first highly conductive composite material member.

10. A device according to claim 9, wherein both the first part of the second electrode and the second part of the second electrode are provided with contacts, and the contacts of the first part of the first electrode, the first highly conductive composite material member, and the contacts of the first part of the second electrode are disposed in a line with one another.

11. A polymeric substrate circuit protection device comprising:
a substrate, comprising a first conductive composite material portion and a second conductive composite material portion; wherein the first conductive composite material member is a conductive composite material having PTC features , and the second conductive composite material member has more than twenty times the conductivity of the first conductive composite material member;
a first electrode and a second electrode disposed on a first surface and a second surface of the substrate, respectively for covering the substrate;
a first part and a second part of the first electrode, which are discontinuous, provided on the first electrode, wherein the first part of the first electrode is electrically connected to the second electrode through the second conductive composite material member under the first part of the first electrode, and an insulating layer is disposed at the discontinuous portion of the first part and the second part of the first electrode.

12. The device according to claim 11, wherein the second electrode comprises a first part and a second part, which are discontinuous, wherein the first part of the first electrode is electrically connected to the first part of the second electrode through the second conductive composite material member under the first part of the first electrode.

13. The device according to claim 12, wherein the second part of the first electrode electrically connects to the second part of the second electrode through the second conductive composite material member under the second part of the first electrode.

14. The device according to claim 11, wherein the first conductive composite material member is made from polyethylene and carbon black.

15. The device according to claim 11, wherein the first surface and the second surface of the substrate are a top surface and a bottom surface, respectively.

16. The device according to claim 11, wherein the second electrode comprises the first part and the second part, which are discontinuous, the first part of the first electrode is electrically connected to the first part of the second electrode through the second conductive composite material member under the first part of the first electrode; and both the first part of the first electrode and the second part of the first electrode comprise contacts, the contacts of the first part of the first electrode being disposed in a line with the second conductive composite material member under the first part of the first electrode.

17. The device according to claim 11, wherein the second electrode comprises the first part and the second part, which are discontinuous, the first part of the first electrode is electrically connected to the first part of the second electrode through the second conductive composite material member under the first part of the first electrode; and both the first part of the first electrode and the second part of the first electrode comprise contacts, the contacts on the first part of the first electrode being not disposed in a line with the second conductive composite material member under the first part of the first electrode.
